(19) United States
(12) Patent Application Publication
(10) Pub. No.: US 2026/0129840 A1
(43) Pub. Date: May 7, 2026

(54) STAGGERED BIT LINES FOR ADVANCED DRAM

(71) Applicant: Applied Materials, Inc., Santa Clara, CA (US)

(72) Inventors: Zhijun CHEN, San Jose, CA (US); Fredrick FISHBURN, Aptos, CA (US); Raghuveer S. MAKALA, Campbell, CA (US)

(73) Assignee: Applied Materials, Inc., Santa Clara, CA (US)

(21) Appl. No.: 18/939,111

(22) Filed: Nov. 6, 2024

(51) Int. Cl. H10B 12/00

(52) U.S. Cl. CPC H10B 12/482; H10B 12/01; H10B 12/315; H10B 12/488

(57) ABSTRACT

The present technology includes vertical cell dynamic random-access memory (DRAM) structures with improve bit line capacitance. Structures include a plurality of lower bit lines arranged in a first horizontal direction in a first horizontal plane. Structures include a plurality of upper bit lines arranged in the first horizontal direction in a second horizontal plane, where the first horizontal plane is vertically spaced apart from the second horizontal plane. Structures include one or more word lines arranged in a second horizontal direction. Structures include one or more channels extending in a vertical direction that is generally orthogonal to the first horizontal direction and the second horizontal direction such that the plurality of lower bit lines and plurality of upper bit lines intersect with a source/drain region of the one or more channels, and the one or more word lines intersect with a gated region of the one or more channels.

### TECHNICAL FIELD

This disclosure generally describes designs for advanced memory devices, such as 4F² dynamic random-access memory (DRAM), 3D DRAM, and other advanced memory devices. More specifically, this disclosure describes advanced memory arrays with improved bit line capacitance.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries.

Dynamic random-access memory (DRAM) architectures continue to scale down over time. For example, a one transistor, one capacitor (1T-1C) DRAM cell architecture has successfully scaled down from an 8F² size to a 6F² size (where F is the minimum feature size). Further design scheme changes from 6F² to 4F² may help further improve area density. As devices continue to scale down, there is a desire to improve the capacitance of the device. However, advanced design schemes exhibit increased bit line parasitic capacitance, as the bit line sensing margin also decreases with decreasing cell size. Thus, there is a need in the industry to improve one or more features of advanced memory devices.

### BRIEF SUMMARY

The present technology is generally directed to vertical cell dynamic random-access memory (DRAM) structures. Structures include one or more lower bit lines arranged in a first horizontal direction in a first horizontal plane. Structures include one or more upper bit lines arranged in the first horizontal direction in a second horizontal plane, where the first horizontal plane is vertically spaced apart from the second horizontal plane. Structures include one or more word lines arranged in a second horizontal direction. Structures include a plurality of memory cell transistors each having a source/drain region and a channel extending in a vertical direction that is generally orthogonal to the first horizontal direction and the second horizontal direction, such that the one or more lower bit lines and or the one or more upper bit lines electrically connects to the source/drain region of a respective transistor of each transistor of the plurality of memory cell transistors, and the one or more word lines intersects with the channel of a respective transistor of the plurality of memory cell transistors.

In embodiments, structures include a plurality of cell transistors arranged in a plurality of rows. In more embodiments, the one or more lower bit lines contact one or more transistors in two or more spaced apart first rows of the plurality of rows, spaced apart in the first horizontal direction. Embodiments include where the one or more lower bit lines contact one or more cell transistors in two or more spaced apart second rows of the plurality of rows, spaced apart in the first horizontal direction. Furthermore, in embodiments, a respective one of the first rows of the plurality of rows is disposed between two of the second rows of the plurality of rows. Additionally or alternatively, in embodiments, the one or more lower bit lines include a first portion of lower bit lines and a second portion of lower bit lines, where the first portion of lower bit lines extends along first rows of the plurality of rows, and the second portion of lower bit lines extends along second rows of the plurality of rows. Moreover, in embodiments, the one or more upper bit lines include a first portion of upper bit lines and a second portion of upper bit lines, wherein the first portion of upper bit lines extends along second rows of the plurality of rows, and the second portion of upper bit lines extends along first rows of the plurality of rows. In embodiments, structures include an interconnect extending between a bit line of the first portion of lower bit lines and a bit line of the second portion of upper bit lines. In further embodiments, structures include an interconnect extending between a bit line of the first portion of upper bit lines and a bit line of the second portion of lower bit lines. Further, in embodiments, at least one of the one or more word lines is shared between adjacent cell transistors.

The present technology is also generally directed to methods of forming vertical cell dynamic random-access memory (DRAM) structures. Methods include forming one or more first bit line contacts to at least a first portion of cell transistors of a plurality of cell transistors. Methods include depositing one or more lower bit lines arranged in a first horizontal direction connected to at least a first portion of the cell transistors. Methods include depositing an isolation material over the one or more lower bit lines. Methods include forming one or more second bit line contacts to at least a second portion of cell transistors, where each cell transistor of the at least a second portion of the cell transistors is disposed between cell transistors of the first portion of cell transistors. Methods include forming one or more upper bit lines over the isolation material connected to the second portion of cell transistors.

In embodiments, the one or more first bit line contacts are in contact with each cell transistor of the plurality of cell transistors. Moreover, in embodiments, the one or more first bit line contacts are in contact with cell transistors in spaced apart rows of the plurality of cell transistors. Embodiments include where forming the one or more lower bit lines includes forming a first portion of lower bit lines in a first portion of rows and a second portion of lower bit lines in a second portion of rows, wherein each row of the second portion of rows is disposed between rows of the first portion of rows. In further embodiments, at least a portion of the one or more second bit line contacts is formed to the second portion of lower bit lines. In yet more embodiments, forming the one or more upper bit lines includes forming a first portion of upper bit lines in the second portion of rows and a second portion of upper bit lines in the first portion of rows, where each row of the second portion of rows is disposed between rows of the first portion of rows. In embodiments, methods include forming one or more interconnects between a bit line of the second plurality of upper bit lines to a bit line of the first plurality of lower bit lines. Furthermore, in embodiments, methods include forming one or more second bit line contacts to the second portion of the cell transistors comprising forming one or more junctions.

The present technology is also generally directed to semiconductor processing systems. Systems include a system controller configured to form one or more first bit line contacts to at least a first portion of cell transistors of a plurality of cell transistors, in a first processing chamber. Systems include a system controller configured to deposit one or more lower bit lines arranged in a first horizontal direction connected to at least the first portion of the cell transistors. Systems include a system controller configured to deposit an isolation material over the plurality of lower bit lines. Systems include a system controller configured to form one or more second bit line contacts to at least a second portion of cell transistors, where each cell transistor of the at least a second portion of cell transistors is disposed between cell transistors of the first portion of cell transistors. Systems include a system controller configured to form one or more upper bit lines over the isolation material connected to the second portion of cell transistors. In embodiments, a second processing chamber, a third processing chamber, and an optional fourth processing chamber, are contained within a cluster tool having a shared vacuum environment; and the system is configured to perform one or more operations in the second processing chamber or third processing chamber.

Such technology may provide numerous benefits over conventional systems and techniques. For example, the processes and systems may prevent direct coupling of adjacent bit lines, reducing bit line capacitance. Additionally, the processes and systems may significantly improve electrical properties of the semiconductor structures by reducing bit line and contact capacitance, as well as allow for improved isolation of adjacent cells. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 2 shows selected operations in a formation method according to embodiments of the present technology.

FIG. 3A shows a schematic view of a semiconductor structure according to embodiments of the present technology.

FIG. 3B shows a schematic view of a semiconductor structure according to embodiments of the present technology.

FIG. 3C shows a schematic view of a semiconductor structure according to embodiments of the present technology.

FIG. 3D shows a schematic view of a semiconductor structure according to embodiments of the present technology.

FIG. 3E shows a schematic view of a semiconductor structure according to embodiments of the present technology.

FIG. 3F shows a schematic view of a semiconductor structure according to embodiments of the present technology.

FIG. 3G shows a schematic view of a semiconductor structure according to embodiments of the present technology.

FIG. 4 shows a schematic view of a semiconductor structure according to embodiments of the present technology.

FIG. 5A shows a schematic view of a semiconductor structure according to embodiments of the present technology.

FIG. 5B shows a schematic view of a semiconductor structure according to embodiments of the present technology.

FIG. 5C shows a top down view of a semiconductor structure according to embodiments of the present technology

FIG. 6 shows a top-down schematic view of a bit line structure according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Historically, DRAM chip bit densities have been increasing by approximately 25% node over node. However, the node over node increase in bit density has trended down to closer to 20% for the more recent generations, mainly due to the challenges with scaling the cell area. Cell design architecture for modern DRAM technology has been based on 6F² geometry, where “F” is the minimum feature size for a given technology node. Switching from 6F² to 4F² cell architecture could result in a 33% increase in bit density at the same technology node. In addition, patterning difficulties for 4F² DRAM are greatly reduced as compared to 6F². This is due at least in part to the fact that in the 4F² DRAM scheme, the capacitor and bit line are located at two ends of a vertical cell transistor, instead of tightly packed on the same side as in 6F² DRAM.

However, 4F² DRAM design comes with its own challenges. For example, 4F² memory cells have the transistor channel disposed between the bit line and the capacitor layers. Thus, when a capacitor is placed on top of a vertical channel, the bit line must be formed at the bottom of the vertical channel, which requires a continuous line of material as the bit line runs through the entire length of the cell block. However, unlike 6F², where a storage node contact may shield adjacent bit lines and reduce bit line to bit line capacitance, bit lines in 4F² may directly face an adjacent bit line, resulting in bit line capacitance that is problematically high. This problem is only compounded by the desire to continue to decrease cell sizes, as the bit line capacitance increase may be more significant than the sense amplifier can effectively handle at given cell capacitor capacitance in the shrinking cell, creating an even lower sense margin. Namely, such a configuration results in a lower signal to noise ratio than device design needs.

The present technology overcomes these and other problems by providing devices and methods of forming such devices that have reduced bit line capacitance. Namely, the present technology has surprisingly found that by vertically staggering adjacent bit lines, direct coupling is drastically, if not completely reduced. Furthermore, the present technology has found that in embodiments, each bit line may have a lower portion vertically offset from an upper portion, and each bit line may have an opposite vertical orientation of upper and lower portions from adjacent bit lines, allowing for standard contact formation, while also drastically reducing direct coupling of adjacent bit lines. Such a design may also allow for staggered contacts, such that a single bit line may contact every other cell. In such a manner, contact capacitance may be reduced, as well as isolation of neighboring cells within an array, even when using shared word lines for adjacent cells. Thus, the present technology may provide advanced DRAM arrays, such as 4F² arrays and 3D DRAM arrays, as examples, with excellent electrical properties.

Although the remaining disclosure will routinely identify specific deposition and etch processes utilized for forming vertical cell access array transistors (VCAATs), such as a 4F² DRAM device, it will be readily understood that the systems and methods are equally applicable to other memory devices, particularly vertically oriented devices, as well as processes for forming such devices. Accordingly, the technology should not be considered to be so limited as for use with these specific devices or systems alone. The disclosure will discuss one possible semiconductor device that may include one or more components, utilizing one or more power lines and/or signal lines according to embodiments of the present technology before additional variations and adjustments to this apparatus according to embodiments of the present technology are described.

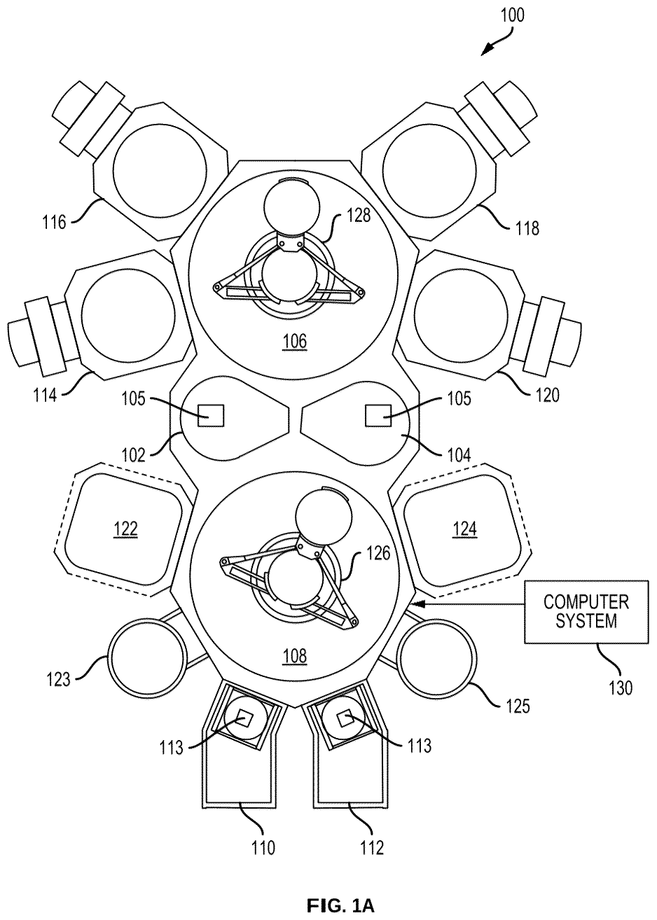

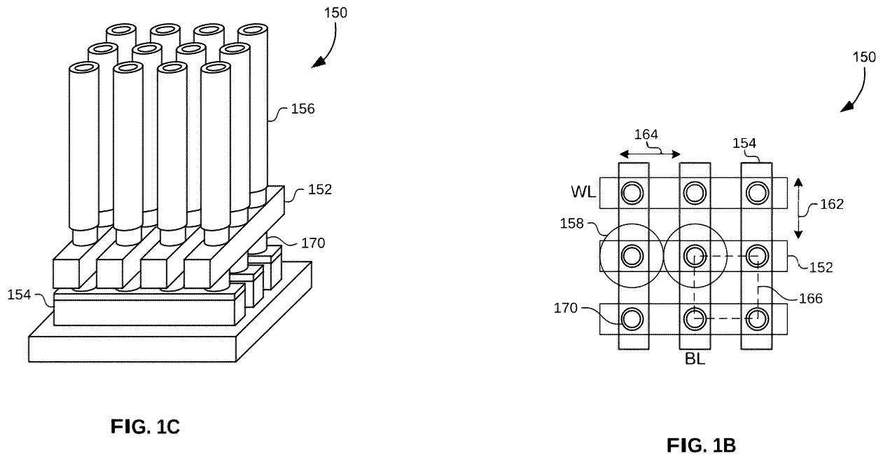

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108 and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general-purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B and 1C illustrate top and perspective views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

A plurality of vertical memory cells may be arranged over intersections between the plurality of word lines 152 and the plurality of bit lines 154. Each of the plurality of vertical memory cells may include a vertical transistor, which may be referred to as a vertical pillar transistor or vertical column transistor. A channel material for the transistor may be formed from a single-crystalline silicon, poly-crystalline silicon, amorphous silicon, silicon carbide, silicon germanium, germanium, an oxide semiconductor, including indium gallium zinc oxide, 2D materials including molybdenum disulfide, gallium nitride, carbon nanotubes, graphene, boron arsenide, combinations thereof, or any other substrates discussed in greater detail herein. Furthermore, dopants may be introduced based upon the device need, for any one or more of the materials discussed herein. This silicon channel may be formed by etching the substrate, as shown in the illustrated embodiments, or may be deposited onto the substrate, depending upon the desired device.

Substrate materials may include bulk substrates, epitaxially grown substrates (single component, e.g. Si on Si; or multiple component, e.g. Si on SiGe or Si on SiGe on Si), silicon, silicon germanium (SiGe), silicon on insulator (SOI), silicon germanium on insulator (SGOI), indium antimonide, lead telluride compound, indium arsenide, indium phosphide, and/or gallium arsenide, as well as any one or more substrate materials discussed above, on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate includes a semiconductor material, e.g., silicon (Si), n-doped Si (e.g. P or As doped Si), p-doped Si (e.g. B doped Si), carbon (C), germanium (Ge), silicon germanium (SiGe), germanium tin (GeSn), other semiconductor materials, or any combination thereof. In one or more embodiments, the substrate includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

Thus, in embodiments, the semiconductor or channel material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element, e.g. P and/or As, during manufacture. The term n-type comes from the negative charge of the electron. In n-type semiconductors, electrons are the majority carriers and holes are the minority carriers. As used herein, the term “p-type” refers to semiconductors that are created by doping an intrinsic semiconductor with an electron donor element, e.g. B and/or Ga, during manufacture. As opposed to n-type semiconductors, p-type semiconductors have a larger hole concentration than electron concentration. In p-type semiconductors, holes are the majority carriers and electrons are the minority carriers.

Each of the plurality of vertical memory cells may also include a vertical capacitor 156. The vertical memory cell may operate by storing a charge on the vertical capacitors 156 to indicate a saved memory state. However, while FIGS. 1B and 1C illustrate the arrangement of the vertical transistors and capacitors in a rectangular generally orthogonal grid pattern (where “generally orthogonal” may be within about 10° from orthogonal, such as less than or about 7.5°, such as less than or about 5°, such as less than or about 2.5°, such as less than or about 1° from orthogonal, or any ranges or values therebetween, where “generally” may be utilized to similarly vary “vertical”, “horizontal” and the like), it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166 for this conventional 4F² memory array for comparison to the simple memory array described below. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166.

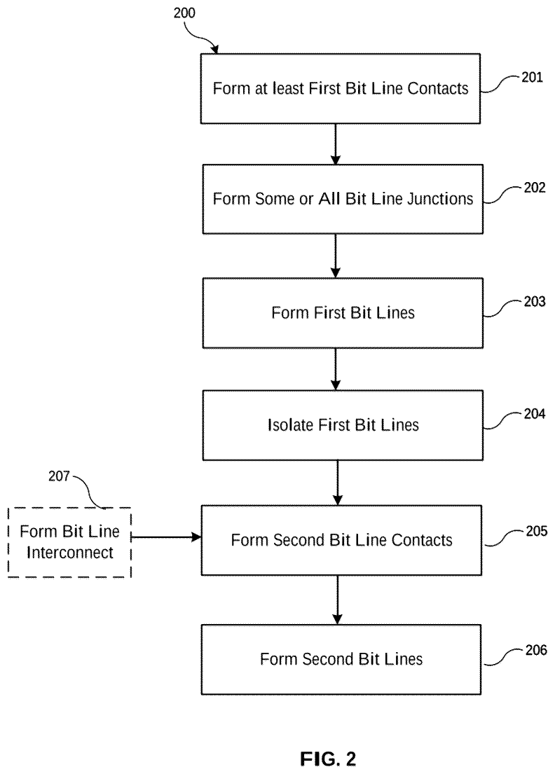

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically with capacitors formed before bit lines, it should be understood that the opposite order which is to form bit lines before capacitors may be utilized, as well as other orientations for non-vertical cell transistors.

Method 200 may include additional operations prior to initiation of the listed operations. For example, additional processing operations may include forming structures on a semiconductor substrate, which may include both forming and removing material as well as one or more optional wafer bonding processes. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations shown schematically in the Figures, the illustrations of which will be described in conjunction with the operations of method 200. It is to be understood that the Figures illustrate only partial schematic views, and a semiconductor substrate may include further components as illustrated in the figures, as well as alternative components, of any size or configuration that may still benefit from aspects of the present technology.

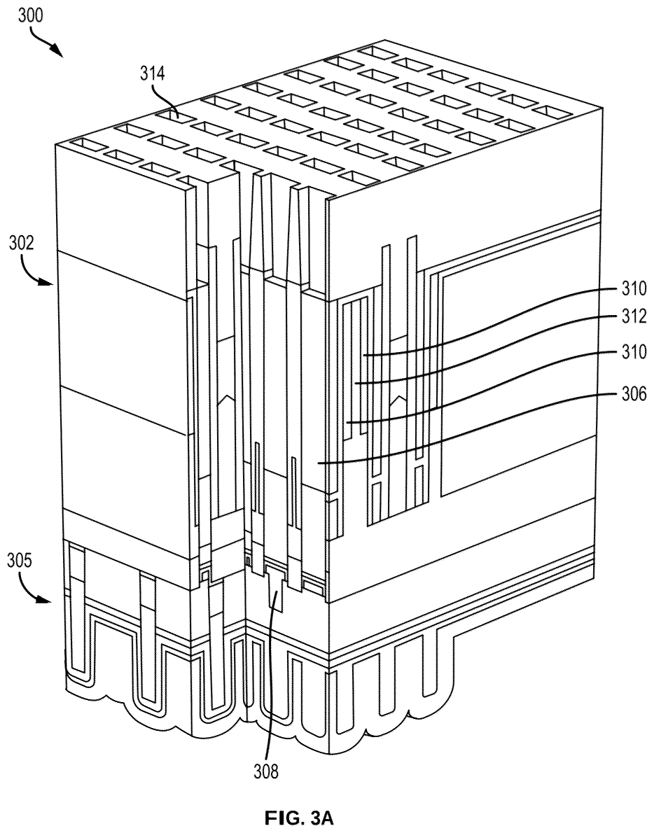

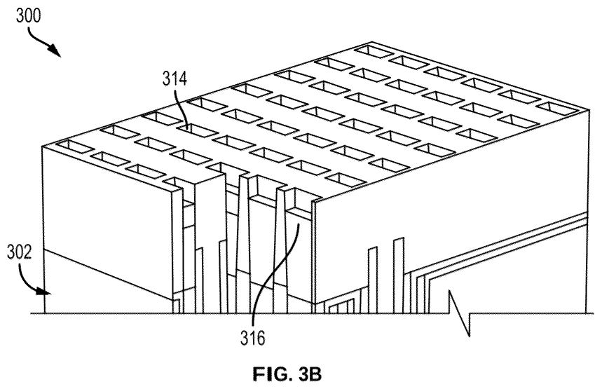

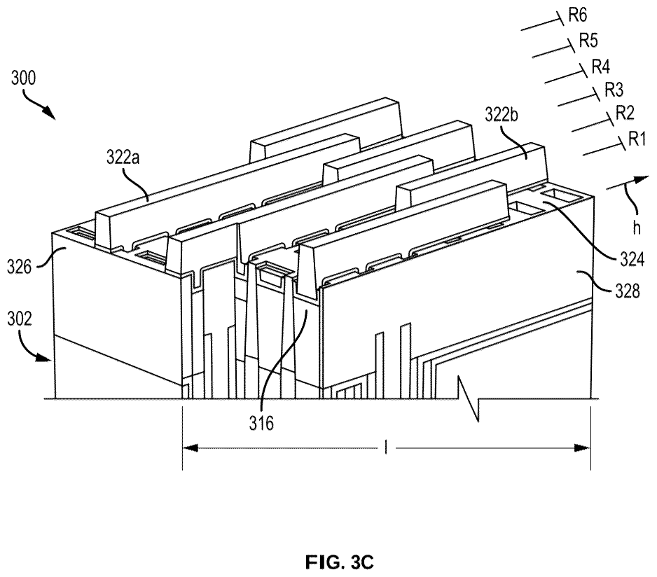

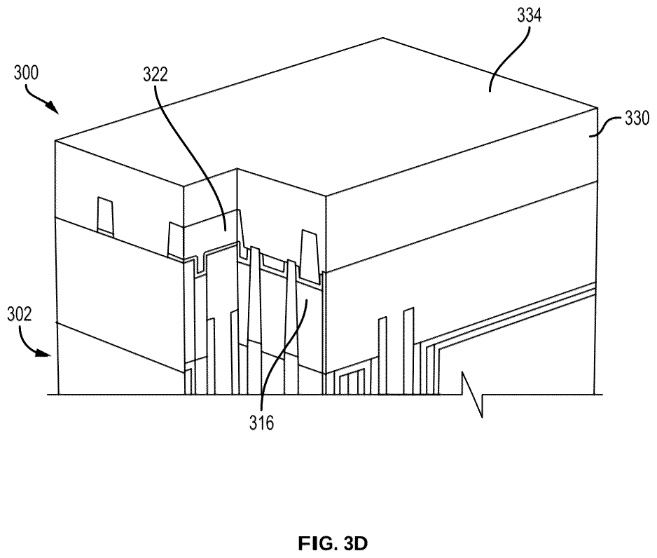

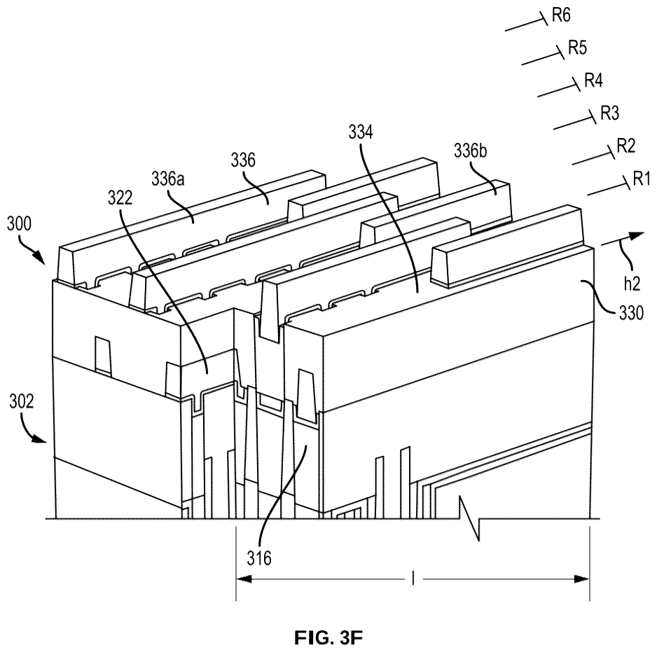

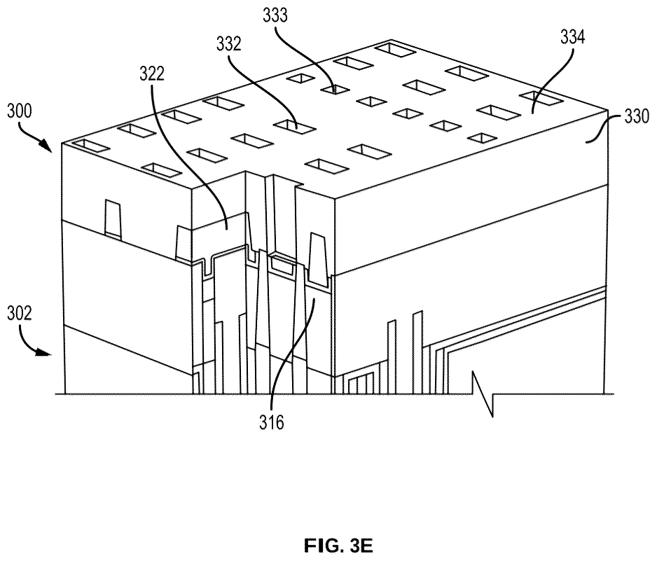

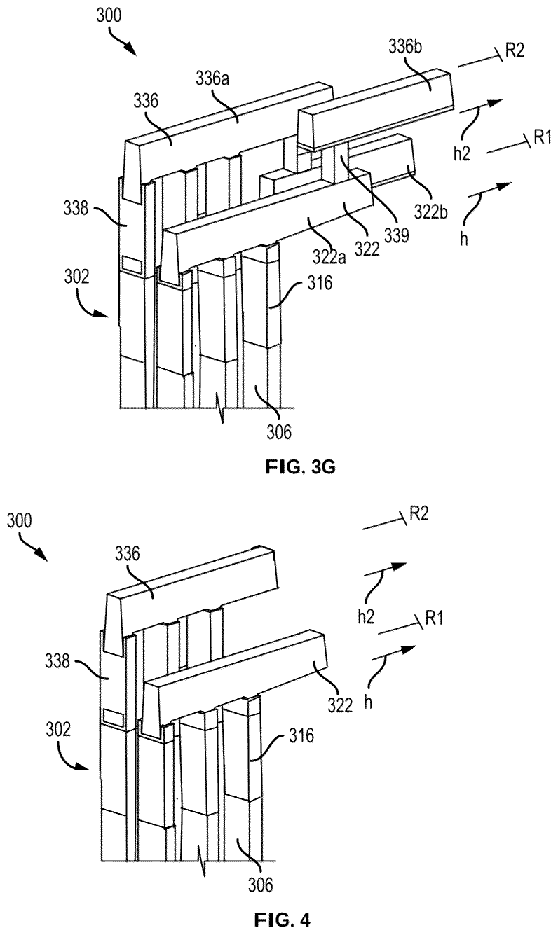

Method 200 may or may not involve optional operations to develop the semiconductor structure to a particular fabrication operation. It is to be understood that method 200 may be performed on any number of semiconductor structures 300 as illustrated in the Figures, including exemplary structures on which a selective deposition material may be formed. As illustrated in FIG. 3A semiconductor structure 300 may include a DRAM array 302 having one or more features or components thereof.

Moreover, while various deposition and fill processes will be described, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

In embodiments, the DRAM array 302 may include one or more cell transistors having a channel 306. Each cell transistor may be a vertical cell structure, as discussed above, and may therefore include a channel 306, which may be or include any one or more of the substrate materials discussed above. In the illustrated embodiments, the one or more cell transistors are shown as having storage node contacts 308 formed in contact with a first end of channel 306 such as in a source/drain region at a first end of the channel 306, connected to one or more storage devices 305. However, it should be understood that, in embodiments, the storage node contacts 308 may be formed after one or more of the operations discussed herein.

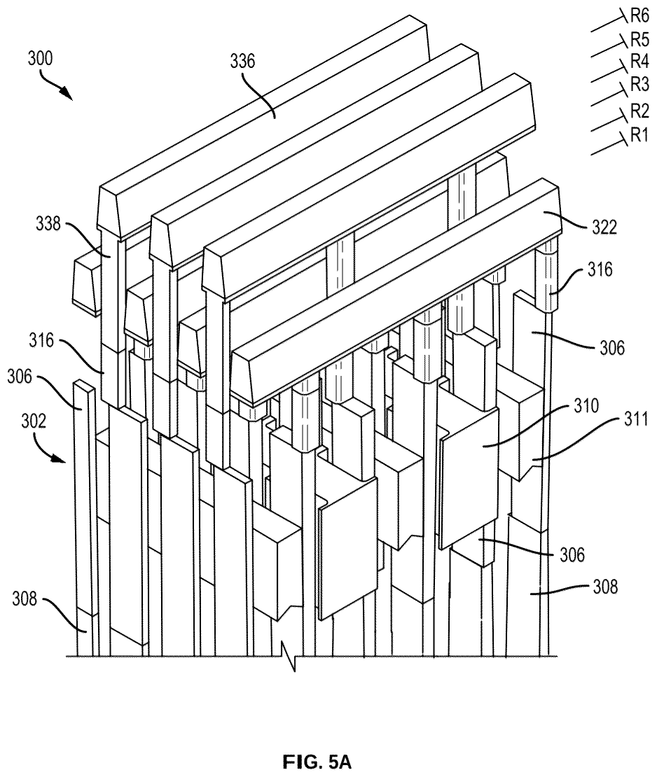

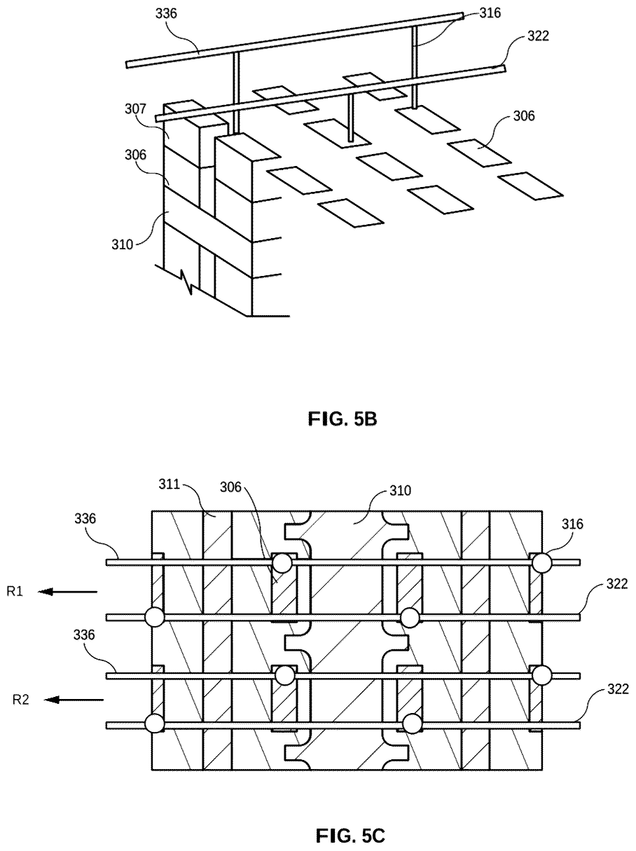

Nonetheless, referring again to FIG. 3A, each cell transistor may include a gate 310 in a gated region of channel 306. In FIG. 3A, the gate 310 is shown spaced apart from an adjacent gate 310 (e.g. of an adjacent channel 306, such as cells that share an edge or border) by one or more dielectric materials 312. Namely, as known in the art, in current systems, it is necessary to electrically isolate channels 306 of adjacent cell transistors by separating adjacent gates, such as with a dielectric material 312. However, as will be discussed in greater detail in regards to FIG. 5A-5C, the devices and systems according to the present technology may allow for a shared gate or wordline between adjacent cells, as staggered bit line contacts allow for an alternative electrical isolation of the cells.

While the DRAM array 302 is illustrated as having one or more components formed therein (e.g. one or more cells, one or more channels, one or more word lines, and the like), and being connected to one or more storage devices 305, it should be clear that such components may also be formed after the bit line formation discussed herein. Nonetheless, in embodiments, the present technology may include forming one or more bit line contact vias 314 at operation 201. As illustrated in FIG. 3A, in embodiments, it may be desired to form a bit line contact via 314 for each cell transistor of the DRAM array 302. However, it may be desired to form only a portion of the bit line contact vias 314 corresponding to spaced apart cell transistors or staggered cell transistors (e.g. every other cell or non-adjacent cell transistors), in order to further isolate the cell transistors and channels 306. Furthermore, in embodiments, it may be desired to only etch a portion of the vias 314, such as a portion of the vias corresponding to contacts for lower bit lines, such that a second portion of the vias corresponding to contacts to upper bit lines may be formed after isolation of the lower bit lines. In addition, in embodiments, bit line contact formation may be achieved after formation of the one or more vias through dielectric materials above channel material 306, or without forming the vias by subtractive etch of a continuous contact layer (including e.g. junction, silicide, and metals) into isolated islands followed by dielectric back fill, or by recessing the channel material 306, or combination of such. Nonetheless, in embodiments, at least a portion of the bit line contact vias 314 are etched at operation 201.

Referring next to FIG. 3B, bit line contacts 316, including junctions thereof, may be formed at operation 202. As illustrated, junction formation may include doping a portion of the channel opposite the storage node junction 308 (if already formed, or opposite the location of the storage node junction) at a second end of channel 306 in contact with a source/drain region at a second end of the channel 306, such as with one or more of the dopants discussed above or by depositing one or more doped and undoped material layers over the respective channel to form source/drain regions. After junction formation, a silicide contact may be formed. For instance, a metal layer may be applied over a junction region which is subsequently exposed to a silicidation process, forming metallized contacts 316. In embodiments, the metal layer may be tungsten, molybdenum, titanium, zirconium, nickel, hafnium, cobalt, tin, tantalum, platinum, iron, niobium, palladium, a metal-containing species thereof, alloys thereof, or combinations thereof. Alternatively, the silicide may be formed using a precursor that directly reacts with the channel material to form a desired metal-channel material layer without a subsequent anneal. Thus, the resulting interface may be a metallized layer of any one or more of the above metals and the channel material, such as silicon. In such an example only, the interface layer may be a titanium silicide, molybdenum silicide, hafnium silicide, or a combination thereof. In embodiments, when Si based material is chosen as BL “metal”, a silicide may not be needed.

While FIG. 3B illustrates that a bit line contact 316 is formed at each cell transistor and channel 306 of the DRAM array 302, it should be understood that, in embodiments, it may be desired to only form a portion of the bit line contacts 316, such as a portion corresponding to contacts for lower bit lines, such that a second portion of the contacts corresponding to upper bit lines may be formed after isolation of the lower bit lines. Nonetheless, in embodiments, at least a portion of the bit line contacts 316 are formed at operation 202.

Moving next to FIG. 3C, lower bit lines 322, or a portion thereof, are formed at operation 203. As illustrated, lower bit lines 322 are formed in a first horizontal plane h, overlying a top surface 324 of DRAM array 302. Namely, as shown, lower bit lines 322 may generally be spaced apart, such that one bit line of the plurality of lower bit lines is spaced apart from a second bit line of the plurality of lower bit lines. Stated differently, at least a portion of the lower bit lines 322 may be formed in contact with cell transistors in alternating rows (e.g. of rows R1-R6). As an example only, six rows R1-R6 may be illustrated in FIG. 3C, where some or all of lower bit lines 322 may be formed predominantly in alternating rows, such as rows R1, R3, and R5 and/or R2, R4, and R6, as an example only. Thus, due to the increased spacing between lower bit lines 322, decreased bit line capacitance may be obtained.

However, referring to FIGS. 3C to 3F, in embodiments, each row may include bit lines formed on more than one vertical plane. Thus, in embodiments, each row may be formed from both a lower bit line 322 segment and an upper bit line 336 segment. For instance, it is illustrated that a lower bit line segment 322a or 322b may extend only partially across the length/of the DRAM array 302. In embodiments, the lower bit lines 322 may include first lower bit lines 322a that extends from a first side 326 or near a first side 326 of the DRAM array 302, to an interior location along length/of the DRAM array, and may therefore terminate prior to reaching second side 328 of the DRAM array. For instance, in embodiments, the first lower bit lines 322a of the lower bit lines 322 may extend to a location that along least a portion of the length/of the DRAM array 302. In the illustrated embodiment, first lower bit lines 322a extend approximately halfway across the array. For instance, such an arrangement may provide for an even distribution of capacitance across lower bit line segments 322 and upper bit line segments 336. However, while illustrated that first lower bit lines 322a and second lower bit lines 322b are continuous from a first point to a second point within the array, it should be clear that lower bit lines 322 may be discontinuous, allowing for formation of a portion of upper bit lines 336 to be disposed between and separate first portions 322a in the same row.

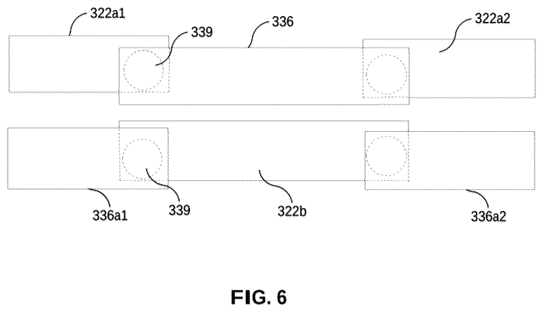

For instance, referring to FIG. 6, first lower bit lines 322a may include a first portion 322al spaced apart from a second portion 322a2, by one or more upper bit line segments 336. In such embodiments, lower bit lines 322 may be formed over approximately 50% of the channels 306 of cell transistors (e.g. about 40% to about 60%, about 42% to about 58%, about 44% to about 56%, about 46% to about 54%, about 48% to about 52% of the cells, or any ranges or values therebetween) in a respective row, in a continuous or discontinuous manner to allow for even capacitance distribution even when discontinuous bit lines are utilized. In such a manner, the first lower bit lines 322a of the lower bit lines 322 may contact some or all of the cell transistors in a respective row. However, while only two portions of the first lower bit lines are illustrated, it should be clear that lower bit lines 322 may contain greater than two portions, greater than three portions, greater than four portions, greater than five portions, or more.

Furthermore, the semiconductor structure 300 may also include a second lower bit lines 322b of the lower bit lines 322 extending along alternating rows to first lower bit lines 322a (e.g. rows R2, R4, R6 in the illustrated example). Thus, in embodiments, a second lower bit lines 322b of the lower bit lines 322 extends from a second side 328 or near a first side 328 of the DRAM array 302, towards first side 326 to an interior location along length/of the DRAM array in alternating rows from first lower bit lines 322a, and may therefore terminate prior to reaching first side 326 of the DRAM array. For instance, in embodiments, the second lower bit lines 322b of the lower bit lines 322 may extend to a location along least a portion of the length/of the DRAM array 302. In the illustrated embodiment, second lower bit lines 322b extend approximately halfway across the array. For instance, such an arrangement may provide for an even distribution of capacitance across lower bit lines 322 and upper bit lines 336. However, while illustrated that second lower bit lines 322b are continuous from a first point to a second point within the array, it should be clear that second lower bit lines 322b may be discontinuous, allowing for formation of a portion of upper bit lines 336 to be disposed between and separate second lower bit lines 322b in the same row. In such embodiments, second lower bit lines 322b may therefore be formed over approximately 50% of the channels 306 of the cell transistors (e.g. about 40% to about 60%, about 42% to about 58%, about 44% to about 56%, about 46% to about 54%, about 48% to about 52% of the cells, or any ranges or values therebetween) in a respective row, in a continuous or discontinuous manner to allow for even capacitance distribution even when discontinuous bit lines are utilized. In such a manner, the second lower bit lines 322b of the lower bit lines 322 may contact some or all of the cell transistors in a respective row, which may be a row directly adjacent to a row containing a first lower bit line 322a of the lower bit lines.

Thus, in embodiments, the second lower bit lines 322b of the lower bit lines 322 may only partially overlap (e.g. extend alongside some or a portion of) or not overlap (e.g. not extend alongside some or a portion of) the first lower bit lines 322a of an adjacent first bit line. For instance, in embodiments, the first lower bit lines 322a and second lower bit lines 322b may overlap or extend along less than or about 30% of the length of a first portion or second portion of an adjacent first word line 322, such as less than or about 28%, less than or about 26%, less than or about 24%, less than or about 22%, less than or about 20%, less than or about 18%, less than or about 16%, less than or about 14%, less than or about 12%, less than or about 10%, less than or about 8%, less than or about 6%, less than or about 4%, less than or about 2%, less than or about 1% of the length of an adjacent first lower bit lines 322a and second lower bit lines 322b may overlap, or any ranges or values therebetween. Stated differently, the first lower bit lines 322a and second lower bit lines 322b may overlap or extend along each other for about 10 cells or less, less than or about 9 cells, less than or about 8 cells, less than or about 7 cells, less than or about 6 cells, less than or about 5 cells, less than or about 4 cells, less than or about 3 cells, less than or about 2 cells about 1 cell, or less, or any ranges or values therebetween. In embodiments, the cell overlap may occur at each portion, if multiple portions of the lower bit lines are utilized. In such a manner, bit line capacitance may be drastically reduced due to the reduced direct coupling between adjacent bit lines, while also facilitating end of line contacts to the device.

Nonetheless, in embodiments, it should be clear that the lower bit lines 322 may extend across an entire length/of the DRAM array 302 (see, e.g., FIGS. 4 and 5A-5C), from first side 326 to second side 328 of the DRAM array 302. Thus, in embodiments, lower bit lines 322 may be formed continuously across the length l of the DRAM cell 302 in alternating rows.

In embodiments, the one or more lower bit lines 322 may be formed by applying a layer of conductive material over top surface 324 of the DRAM array 302. After deposition, the lower bit lines 322 may be patterned and etched, forming the first bit line structures illustrated in FIG. 3C. Furthermore, during deposition, each of the contacts 316 may be contacted with the conductive material, filling the remainder of vias 314 with conductive material. Thus, the conductive material may be placed for each channel 306, including cells not directly contacted by lower bit lines 322, for later contact with one or more further bit lines. However, as discussed above, in embodiments, one or more vias 314 may be formed after formation of lower bit lines 322, and thus, may not be filled with conductive material during formation of lower bit lines 322.

In embodiments, conductive materials may include titanium nitride, titanium silicon nitride, polycrystalline silicon, molybdenum nitride, doped or undoped molybdenum silicide, titanium, tantalum, ruthenium, tungsten, molybdenum, platinum, nickel, cobalt, tantalum nitride, tungsten nitride, tungsten silicide, niobium nitride, titanium aluminide, titanium aluminum nitride, titanium silicide, titanium nitride, titanium silicon nitride, tantalum silicide, tantalum silicon nitride, ruthenium titanium nitride, nickel silicide, cobalt silicide, iridium oxide, ruthenium oxide, ruthenium silicide, ruthenium nitride, alloys thereof, or combinations thereof. In embodiments, conductive materials may include one or more metals, such as titanium, tungsten, ruthenium, molybdenum, titanium nitride, titanium silicide, molybdenum nitride, doped or undoped molybdenum silicide, tungsten nitride, tungsten silicide, ruthenium oxide, ruthenium nitride, alloys thereof, or a combination thereof.

Regardless of the conductive material utilized, as illustrated in FIG. 3D, the lower bit lines may be isolated with one or more dielectric materials 330 at operation 204. As illustrated, the one or more dielectric materials 330 may serve to both isolate the lower bit lines from subsequent conductive material deposition, and also provide a vertical separation between lower bit lines 322 and subsequently formed bit lines. Thus, in embodiment, the one or more dielectric materials 330 may be deposited, or otherwise applied or formed, over top surface 324 and lower bit lines 322. In embodiments, suitable dielectric materials may include silicon nitride, silicon oxide, silicon oxynitride, SiOC, SiCN, and SiOCN, as well as stacks or combinations thereof. It is also possible to isolate the bit lines with air gaps.

Referring next to FIG. 3E, second bit line contact vias 332 may be formed at operation 205. As illustrated, in embodiments, the second bit line contact vias 332 may be formed over cell transistors not directly contacted by lower bit lines 322. Thus, at least a portion of the second bit line contact vias 332 may be formed over one or more cells in rows adjacent to lower bit lines 322 (e.g. not directly above lower bit lines 322). Stated differently, at least a portion of the second bit line contact vias 332 may be formed in alternating rows, such that cells in adjacent rows are not connected to a bit line in the same horizontal plane h/h2. However, as discussed above, in embodiments, the second bit line contact vias 332 may be formed in staggered regions of adjacent rows, corresponding to cell transistors not directly contacted by lower bit lines 322, when each row may include bit lines formed on one or more vertical planes and therefore contain both a lower bit lines 322 segment and an upper bit line 336 segment.

Furthermore, in embodiments where each row may include bit lines formed on more than one vertical plane, optional operation 207 may be utilized to form one or more bit line interconnect vias 333. Such vias may be utilized to form connections between lower bit lines 322 and upper bit lines 336. While the bit line interconnect vias 333 are illustrated as extending in a generally linear manner across top surface 334, it should be understood that, in embodiments, at least a portion of the lower bit lines 322 may be staggered (e.g. a portion of the lower bit lines 322 begin or terminate about 10 cells or less, less than or about 9 cells, less than or about 8 cells, less than or about 7 cells, less than or about 6 cells, less than or about 5 cells, less than or about 4 cells, less than or about 3 cells, less than or about 2 cells about 1 cell, from a first side 326 or second side 328) in order to allow for improved processing, such as etching.

In embodiments, operation 205 may include etching one or more vias, removing a portion of dielectric material 330, in order to electrically connect to one or more contacts 316. As discussed above, in embodiments, operation 205 may therefore include removing dielectric material 330 until conductive material in un-contacted vias 314 (e.g. cells not connected to lower bit lines) is exposed. However, in embodiments, it may be desired to form the full junction and contact to the respective cell at operation 205. In such embodiments, only a portion of channels 306 may be contacted at operation 202. For instance, only cell transistors connected to lower bit lines 322 may be contacted and have a junction formed therebetween at operation 202 Thus, in such embodiments, operation 205 may include etching through dielectric 330 and top surface 324 of DRAM array 302, exposing a top surface of at least a portion of the channels 306, such as cell transistors in two or more spaced apart rows. Furthermore, operation 205 may therefore include subjecting the channel 306 to doping and silicidation, as discussed above in regards to operation 202. Subsequent the doping and silicidation, the contact 316 may be formed and exposed, suitable for connection to subsequently formed bit lines such that the bit lines may be in electrical contact with a source/drain region of channel 306. However, in embodiments, it should be understood that all or at least a portion of junctions may be formed together, such as at operation 202.

After etching of second vias 332, upper bit lines 336 may be formed at operation 206, as illustrated in FIG. 3F. For instance, upper bit lines 336 are formed in a second horizontal plane h2, overlying a top surface 334 of dielectric material 330. Thus, the upper bit lines 336 (and second horizontal plane h2) may be vertically separated from lower bit lines 322 (and/or first horizontal plane h), such as disposed vertically above lower bit lines 322/first horizontal plane h. Namely, in embodiments, at least a portion of the dielectric material 330 is retained between a top surface of the lower bit lines 322 and a bottom surface of the upper bit lines 336.

Further, upper bit lines 336 may generally be spaced apart, such that one bit line of the plurality of upper bit lines 336 is spaced apart from a second bit line of the plurality of upper bit lines 336. Stated differently, at least a portion of the upper bit lines 336 may be formed in contact with junctions in alternating rows such that channels 306 in adjacent rows are not contacted by adjacent upper bit lines 336. As an example only, six rows R1-R6 may be illustrated in FIG. 3F, where some or all of upper bit lines 336 may be formed predominantly in alternating rows, such as rows R2, R4, and R6 and/or R1, R3, and R5. Thus, due to the increased spacing between adjacent upper bit lines 336, decreased bit line capacitance may be obtained.

Referring to FIG. 3F, in embodiments, each row may include bit lines formed on more than one vertical plane as discussed above. Thus, in embodiments, each row may be formed from both a lower bit line 322 segment and an upper bit line 336 segment. For instance, it is illustrated that upper bit lines 336 extend partially across the length/of the DRAM array 302. For instance, first upper bit lines 336a of the upper bit lines 336 extend from a first side 326 or near a first side 326 of the DRAM array 302, to an interior location along length/of the DRAM array, and therefore terminate prior to reaching second side 328 of the DRAM array. For instance, in embodiments, the first upper bit lines 336a of the upper bit lines 336 may extend to a location that along least a portion of the length/of the DRAM array 302. In such a manner, the first upper bit lines 336a of the upper bit lines 336 may contact some or all of the channels 306 of cell transistors in a respective row. In the illustrated embodiment, first portions 336a extend approximately halfway across the array. For instance, such an arrangement may provide for an even distribution of capacitance across lower bit lines 322 and upper bit lines 336. However, while illustrated that first upper bit lines 336a are continuous from a first point to a second point within the array, it should be clear that first upper bit lines 322a may be discontinuous, allowing for formation of a portion of lower bit lines 322 to be disposed between and separate first portions 336a in the same row.

For instance, referring to FIG. 65, first upper bit lines 336a may include a first portion 336al spaced apart from a second portion 336a2, by one or more lower bit line segments 322. In such embodiments, upper bit lines 336 may be formed over approximately 50% of the cell transistors (e.g. about 40% to about 60%, about 42% to about 58%, about 44% to about 56%, about 46% to about 54%, about 48% to about 52% of the cells, or any ranges or values therebetween) in a respective row, in a continuous or discontinuous manner to allow for even capacitance distribution even when discontinuous bit lines are utilized. In such a manner, the first upper bit lines 336a of the upper bit lines 336 may contact some or all of the cell transistors in a respective row. However, while only two portions of the first upper bit lines are illustrated, it should be clear that upper bit lines 336 may contain greater than two portions, greater than three portions, greater than four portions, greater than five portions, or more.

Nonetheless, first upper bit lines 336a may contact a second lower bit lines 322b of lower bit lines 322 via one or more bit line interconnects 339 (shown more clearly in FIG. 3G) in the same row. Thus, in embodiments, each row may have a portion in the first horizontal plane h, and a portion in the second horizontal plane h2, where the first horizontal plane is vertically offset from the second horizontal plane, so as to further improve the case of connecting to the multi-level bit line during downstream processes. Such an arrangement may allow for bit line capacitance to be drastically reduced due to the reduced direct coupling between adjacent bit lines, while also facilitating end of line contacts to the device. Nonetheless, as discussed above, and as shown in FIG. 4, it should be understood that, in embodiments, each row may instead have a bit line in only a single horizontal plane.

Furthermore, the semiconductor structure 300 may also include a second portion 336b of the upper bit lines 336 extending along alternating rows to first upper bit lines 336a (e.g. rows R1, R3, R5 as an example only). Thus, in embodiments, second portion 336b of the upper bit lines 336 extend from a second side 328 or near a second side 328 of the DRAM array 302, towards first side 326 to an interior location along length/of the DRAM array, and therefore terminate prior to reaching first side 326 of the DRAM array. For instance, in embodiments, the second portion 336b of the upper bit lines 336 may extend to a location along least a portion of the length/of the DRAM array 302. In embodiments, the second portion 336b of upper bit lines 336 may extend the same length or a different length than second lower bit lines 322b of lower bit lines 322, in a row adjacent to and vertically above (e.g. not directly above) second lower bit lines 322b of lower bit lines 322. Therefore, the second portion 336b of the upper bit lines 336 may only partially overlap (e.g. extend alongside some or a portion of) or not overlap (e.g. not extend alongside some or a portion of) the first upper bit lines 336a of an adjacent second bit line 336. Furthermore, the second portion(s) 336b may contact lower bit lines 322 (such as first lower bit lines 322a of lower bit lines) via one or more bit line interconnects 339 (shown more clearly in FIG. 3G) in the same row.

In the illustrated embodiment, second portions 336b extend approximately halfway across the array. For instance, such an arrangement may provide for an even distribution of capacitance across lower bit lines 322 and upper bit lines 336. However, while illustrated that second portions 336b are continuous from a first point to a second point within the array, it should be clear that second portions 336b may be discontinuous, allowing for formation of a portion of lower bit lines 322 to be disposed between and separate second portions 336b in the same row. In such embodiments, second portions 336b may therefore be formed over approximately 50% of the channels 306 of cell transistors (e.g. about 40% to about 60%, about 42% to about 58%, about 44% to about 56%, about 46% to about 54%, about 48% to about 52% of the cells, or any ranges or values therebetween) in a respective row, in a continuous or discontinuous manner. In such a manner, the second portion 336b of the lower bit lines 322 may contact some or all of the cell transistors in a respective row, which may be a row directly adjacent to a row containing a first portion 336b of the lower bit lines. While only one bit line interconnect 339 is illustrated per row, it should be understood that more than one bit line interconnect 339 may be utilized per row, such as when the first bit line 322 and/or second bit line 336 is formed from one or more separate sections, as discussed above in regards to FIG. 6. Thus, in such embodiments, each segment may be connected to an adjacent first bi line 322 or second bit line 336 segment using one or more bit line interconnects 339.

Thus, in embodiments, each row may have a portion in the first horizontal plane h, and a portion in the second horizontal plane h2, where the first horizontal plane is vertically offset from the second horizontal plane, so as to further improve the case of bonding to the multi-level bit line. Such an arrangement may allow for bit line capacitance to be drastically reduced due to the reduced direct coupling between adjacent bit lines, while also facilitating end of line contacts to the device. Nonetheless, as discussed above, and as shown in FIG. 4, it should be understood that, in embodiments, each row may instead have a bit line in only a single horizontal plane.

In embodiments, the first upper bit lines 336a and second portion 336b may overlap or extend along less than or about 30% of the length of a first portion or second portion of an adjacent first word line 322, such as less than or about 28%, less than or about 26%, less than or about 24%, less than or about 22%, less than or about 20%, less than or about 18%, less than or about 16%, less than or about 14%, less than or about 12%, less than or about 10%, less than or about 8%, less than or about 6%, less than or about 4%, less than or about 2%, less than or about 1% of the length of an adjacent first upper bit lines 336a and second portion 336b may overlap, or any ranges or values therebetween. Stated differently, the first lower bit lines 322a and second lower bit lines 322b may overlap or extend along each other for about 10 cells or less, less than or about 9 cells, less than or about 8 cells, less than or about 7 cells, less than or about 6 cells, less than or about 5 cells, less than or about 4 cells, less than or about 3 cells, less than or about 2 cells about 1 cell, or less, or any ranges or values therebetween. In embodiments, the cell overlap may occur at each portion, if multiple portions of the lower bit lines are utilized. In such a manner, bit line capacitance may be drastically reduced due to the reduced direct coupling between adjacent bit lines, while also facilitating end of line contacts to the device.

Nonetheless, in embodiments, it should be clear that the upper bit lines 336 may extend across an entire length/of the DRAM cell 302 (see, e.g., FIGS. 4 and 5A-5C), from first side 326 to second side 328 of the DRAM cell 302. Thus, in embodiments, upper bit lines 336 may be formed continuously across the length l of the DRAM cell 302 in alternating rows.

In embodiments, the one or more upper bit lines 336 may be formed by applying a layer of conductive material over top surface 334 of dielectric material 330. After deposition, the upper bit lines 336 may be patterned and etched, forming the first bit line structures illustrated in FIG. 3F. Furthermore, during deposition, bit line interconnects 339 (shown more clearly in FIG. 3G) between lower bit lines 322 and upper bit lines 336 may be formed from the conductive material, filling the remainder of vias 332 with conductive material. Thus, in embodiments, portions of the lower bit lines 322 and upper bit lines 336 in the same row but in separate planes, as well as at least a portion of the cell transistors (such as each cell transistor in embodiments) and first and upper bit lines may be electrically connected.

FIG. 3G illustrates a simplified drawing of the semiconductor structure 300 of FIG. 3F. Namely, as illustrated, lower bit lines 322 may be electrically connected to one or more channels 206 of cell transistors via bit line junctions 316. As shown, a first lower bit lines 322a may directly contact the one or more bit line junctions 316, whereas the second lower bit lines 322b may be disposed outward of the array area a. Nonetheless, as illustrated, lower bit lines may be spaced apart such that a row of cells (R1-R6) is disposed between adjacent lower bit lines 322. Furthermore, as discussed above, in embodiments, first lower bit lines 322a of lower bit lines may be spaced apart in alternating rows, and second lower bit lines 322b of lower bit lines may be spaced apart in alternating rows from further second portions 322b, but may be disposed in one or more rows adjacent to a row containing one or more first portions 322a.

Nevertheless, as illustrated, the semiconductor structure 300 may also contain one or more upper bit lines 336 disposed in a second horizontal plane h2 vertically spaced apart from the lower bit lines 322 in first horizontal plane h. As shown, one or more second bit line contacts 338 may be formed between junctions 316 and upper bit lines 336 in opposite rows as lower bit lines 322. As shown, first upper bit lines 336a first upper bit lines 336a and second portions 336b may directly contact the one or more bit line junctions 316. Nonetheless, as illustrated, upper bit lines may be spaced apart such that a row of cells (R1-R6) is disposed between adjacent lower bit lines 336. Furthermore, as discussed above, in embodiments, first upper bit lines 336a of upper bit lines may be spaced apart in alternating rows, and second portion 336b of upper bit lines may be spaced apart in alternating rows from further second portions 336b, but may be disposed in one or more rows adjacent to a row containing one or more first portions 336a.

Furthermore, one or more bit line interconnects 339 may directly connect a first lower bit lines 322a of lower bit lines with a second portion 336b of upper bit lines and/or first upper bit lines 336a first upper bit lines 336a of upper bit lines with a second lower bit lines 322b of lower bit lines. However, as discussed above, it should be clear that, in embodiments, lower bit lines 322 and/or upper bit lines 336 may extend the entire length/of the semiconductor structure 300 as illustrated in FIG. 4, and may therefore extend in a single plane.

Furthermore, the present technology has found that the bit line arrangement discussed herein may also provide for improved isolation of adjacent cells. For instance, referring to FIGS. 5A-5C, the bit line orientation of the present technology may provide for electrical isolation of adjacent channels 306 without word line separation. For instance, as illustrated, in embodiments, word line 310 may be shared between adjacent channels 306. Namely, instead of forming thin separate word lines and separating adjacent word lines 310 with a dielectric material (such as a dielectric material 312 discussed above), bit lines may “skip” channels 306, and therefore may only contact alternating channels 306 in a respective row as most clearly shown in FIGS. 5B and 5C, allowing for use of a solid fill word line shared between adjacent cells.

For instance, as illustrated in FIG. 5B, which may be a simplified line drawing of FIG. 5A, upper bit line 336 may contact a source/drain region 307 via bit line contact 316 at a second end of the first and a third channel 306 whereas lower bit line 322 may contact a source/drain region 307 via bit line contact 316 at a second end of a second channel 306 in a respective row. Such an arrangement allows for a wordline 310 in contact with a gated region of the channels 306 to be shared between adjacent channels 306 in a respective row.

FIG. 5C shows a further illustration in a top-down orientation. Namely, as shown, the lower bit lines 322 and upper bit lines 336 may be oriented on opposite sides of channels 306. Such an orientation may allow for the lower bit lines 322 and upper bit lines 336 to contact channels 306 in a respective row while leaving row. Nonetheless, as illustrated, due to the electrical separation of adjacent channels by the upper and lower bit lines, a shared word line 310 may be utilized for channels 306 adjacent to one another in a direction generally perpendicular to the direction of the respective row. In addition, FIG. 5C also more clearly shows the orientation of backgate 311.

Thus, in embodiments, instead of utilizing lower bit lines 322 and upper bit lines 336 to contact alternating rows of cells, the lower bit lines 322 may contact a portion of spaced apart channels 306 in a row, and the upper bit lines 336 may contact a second portion of spaced apart channels 306 in the row, such that the channels of the first portion are separated by channels of the second portion. Thus, adjacent cells may be electrically isolated by being connected to a separate bit line, and may therefore not require dielectric isolation of a word line shared by adjacent cells, allowing for word line sharing. However, it should be clear that, in embodiments, the bit lines may also be formed from two or more segments on two or more vertical planes, as discussed above in regards to FIGS. 3A-3G.

However, it should be clear that the contact and bit line orientation of FIGS. 5A-5C can also be utilized with isolated wordlines, such as the word line configuration of FIG. 3A, as the configuration illustrated in FIGS. 5A-5C may also provide for a reduction in bit line contacts, further reducing the bit line capacitance.

It should be appreciated that the specific steps illustrated in the figures provide particular methods of forming 4F² DRAM arrays according to various embodiments. Other sequences of steps may also be performed according to alternative embodiments. For example, alternative embodiments may perform the steps outlined above in a different order. Moreover, the individual steps illustrated in the figures may include multiple sub-steps that may be performed in various sequences as appropriate to the individual step. Furthermore, additional steps may be added or removed depending on the particular applications, as various operations discussed herein may be suitable for other devices. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A vertical cell dynamic random-access memory (DRAM) structure, comprising:
one or more lower bit lines arranged in a first horizontal direction in a first horizontal plane;
one or more upper bit lines arranged in the first horizontal direction in a second horizontal plane, wherein the first horizontal plane is vertically spaced apart from the second horizontal plane;
one or more word lines arranged in a second horizontal direction; and
a plurality of memory cell transistors each having a source/drain region and a channel extending in a vertical direction that is generally orthogonal to the first horizontal direction and the second horizontal direction, such that the one or more lower bit lines or the one or more upper bit lines electrically connects to the source/drain region of a respective transistor of each transistor of the plurality of memory cell transistors, and the one or more word lines intersects with the channel of a respective transistor of the plurality of memory cell transistors.

2. The structure of claim 1, wherein the plurality of memory cell transistors are arranged in a plurality of rows.

3. The structure of claim 2, wherein the one or more lower bit lines electrically connect with one or more transistors in two or more spaced apart first rows of the plurality of rows, the two or more first rows being spaced apart in the first horizontal direction.

4. The structure of claim 3, wherein the one or more upper bit lines contact one or more transistors in two or more spaced apart second rows of the plurality of rows, the two or more second rows being spaced apart in the first horizontal direction.

5. The structure of claim 4, wherein a respective one of the first rows of the plurality of rows is disposed between two of the second rows of the plurality of rows.

6. The structure of claim 2, wherein the one or more lower bit lines comprise a first portion of lower bit lines and a second portion of lower bit lines, wherein the first portion of lower bit lines extends along first rows of the plurality of rows, and the second portion of lower bit lines extends along second rows of the plurality of rows.

7. The structure of claim 6, wherein the one or more upper bit lines comprise a first portion of upper bit lines and a second portion of upper bit lines, wherein the first portion of upper bit lines extends along second rows of the plurality of rows, and the second portion of upper bit lines extends along first rows of the plurality of rows.

8. The structure of claim 7, further comprising an interconnect extending between a bit line of the first portion of lower bit lines and a bit line of the second portion of upper bit lines.

9. The structure of claim 8, further comprising an interconnect extending between a bit line of the first portion of upper bit lines and a bit line of the second portion of lower bit lines.

10. The structure of claim 2, wherein at least one of the one or more word lines is shared between adjacent cell transistors.

11. A method of forming a vertical cell dynamic random-access memory (DRAM) structure, comprising:
forming one or more first bit line contacts to at least a first portion of cell transistors of a plurality of cell transistors;
depositing one or more lower bit lines arranged in a first horizontal direction connected to the one or more first bit line contacts;
depositing an isolation material over the one or more lower bit lines;
forming one or more second bit line contacts to at least a second portion of cell transistors, wherein each cell transistor of the at least a second portion of the cell transistors is disposed between cell transistors of the first portion of cell transistors; and
forming one or more of upper bit lines over the isolation material connected to the one or more second bit line contacts.

12. The method of claim 11, wherein the one or more first bit line contacts are in contact with each cell transistor of the plurality of cell transistors.

13. The method of claim 11, wherein the one or more first bit line contacts are in contact with cell transistors in spaced apart rows of the plurality of cell transistors.

14. The method of claim 11, wherein forming the one or more lower bit lines comprises forming a first portion of lower bit lines in a first portion of rows and a second portion of lower bit lines in a second portion of rows, wherein each row of the second portion of rows is disposed between rows of the first portion of rows.

15. The method of claim 14, wherein at least a portion of the one or more second bit line contacts is formed to the second portion of lower bit lines.

16. The method of claim 15, wherein forming the one or more upper bit lines comprise forming a first portion of upper bit lines in the second portion of rows and a second portion of upper bit lines in the first portion of rows, wherein each row of the second portion of rows is disposed between rows of the first portion of rows.

17. The method of claim 16, further comprising forming one or more interconnects between a bit line of the second portion of upper bit lines to a bit line of the first portion of lower bit lines.

18. The method of claim 13, wherein forming one or more second bit line contacts to the second portion of the cell transistors comprising forming one or more junctions.

19. A semiconductor processing system, comprising:
a system controller configured to
form one or more first bit line contacts to at least a first portion of cell transistors of a plurality of cell transistors, in a first processing chamber;
deposit one or more lower bit lines arranged in a first horizontal direction connected to the one or more first bit line contacts;
deposit an isolation material over the one or more lower bit lines;
form one or more second bit line contacts to at least a second portion of cell transistors, wherein each cell transistor of the at least a second portion of cell transistors is disposed between cell transistors of the first portion of cell transistors; and
form one or more upper bit lines over the isolation material connected to the one or more second bit line contacts.

20. The semiconductor processing system of claim 19, wherein a second processing chamber, a third processing chamber, and an optional fourth processing chamber, are contained within a cluster tool having a shared vacuum environment; and wherein the system is configured to perform one or more operations in the second processing chamber or third processing chamber.
